(19) United States
(12) Patent Application Publication
(10) Pub. No.: US 2025/0372416 A1
(43) Pub. Date: Dec. 4, 2025

(54) LASER TRANSFER STRUCTURE AND LASER TRANSFER METHOD

(71) Applicant: Lextar Electronics Corporation, Hsinchu City (TW)

(72) Inventors: Shiou-Yi KUO, Hsinchu City (TW); Tsung-Hao SU, Hsinchu City (TW); Shun-Hong WANG, Hsinchu City (TW); Wei-Yuan MA, Hsinchu City (TW)

(21) Appl. No.: 18/675,527

(22) Filed: May 28, 2024

(51) Int. Cl. H01L 21/67; B32B 43/00; H01L 25/075

(52) U.S. Cl. CPC H01L 21/67144; B32B 43/006; H01L 25/0753; B32B 2310/0843; B32B 2457/20

(57) ABSTRACT

A laser transfer structure and a method for forming the same are provided. The laser transfer structure includes a carrier, a release layer disposed on the carrier, a first chip disposed on the release layer, and a plurality of first photoresist structures disposed on the carrier and surrounding the first chip. A method for fabricating a display module is also provided.

### TECHNICAL FIELD

The disclosure relates to a laser transfer structure, and in particular, it relates to a laser transfer structure with a ballistic layer and a formation method thereof.

### BACKGROUND

### Description of the Related Art

Micro-LED transfer technology is a method of transferring micro LEDs from a growth substrate to a target substrate during the manufacturing process. The two mainstream technologies in the current micro-LED manufacturing process are stamp transfer and laser transfer.

However, the disadvantage of laser transfer is that the chip is prone to rollover or even rotation during the current laser-transfer process, which reduces the transfer yield.

### SUMMARY

An embodiment of the present disclosure provides a laser transfer structure. The laser transfer structure includes a carrier, a release layer disposed on the carrier, a first chip disposed on the release layer, and a plurality of first photoresist structures disposed on the carrier and surrounding the first chip.

An embodiment of the present disclosure provides a laser transfer method including: providing a first carrier with a chip and a plurality of photoresist structures surrounding the chip disposed on the first carrier; providing a second carrier opposite to the first carrier; and transferring the chip from the first carrier to the second carrier using laser radiation.

An embodiment of the present disclosure provides a method for fabricating a display module including: providing a first carrier with a first chip and a plurality of first photoresist structures surrounding the first chip disposed on the first carrier; providing a second carrier opposite to the first carrier; transferring the first chip from the first carrier to the second carrier using first laser radiation; providing the first carrier with a second chip and a plurality of second photoresist structures surrounding the second chip disposed on the first carrier; transferring the second chip from the first carrier to the second carrier using second laser radiation; providing the first carrier with a third chip and a plurality of third photoresist structures surrounding the third chip disposed on the first carrier; transferring the third chip from the first carrier to the second carrier using third laser radiation; and transferring the first chip, the second chip and the third chip from the second carrier to a display panel.

The laser transfer structure and the forming method thereof of the present disclosure are able to be applied on various electronic devices. In order to make the features and advantages of the present disclosure more readily be understood, various embodiments are given in the subsequent description in conjunction with the accompanying drawings.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion.

FIG. 1 illustrates a cross-sectional view of a laser transfer structure according to some embodiments of the present disclosure.

FIGS. 2A-2C respectively illustrate top views of a laser transfer structure according to some embodiments of the present disclosure.

FIGS. 3A-3C respectively illustrate top views of a laser transfer structure according to some embodiments of the present disclosure.

FIG. 4A illustrates a cross-sectional view of a laser transfer structure according to some embodiments of the present disclosure.

FIG. 4B illustrates a top view of a laser transfer structure according to some embodiments of the present disclosure.

FIG. 5 illustrates a cross-sectional view of a laser transfer structure according to some embodiments of the present disclosure.

FIG. 6 illustrates a cross-sectional view of a laser transfer structure according to some embodiments of the present disclosure.

FIG. 7 illustrates a cross-sectional view of a laser transfer structure according to some embodiments of the present disclosure.

FIGS. 8A-8C respectively illustrate cross-sectional views of a laser transfer method according to some embodiments of the present disclosure.

FIGS. 9A-9Q respectively illustrate cross-sectional views of a method for fabricating a display module according to some embodiments of the present disclosure.

FIG. 10A illustrates a cross-sectional view of a display module according to some embodiments of the present disclosure.

FIG. 10B illustrates a top view of a display module according to some embodiments of the present disclosure.

### DETAILED DESCRIPTION

The following disclosure provides many different embodiments, or examples, for implementing different features of the provided quantum dot composite structures. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat symbols and/or characters of components in different embodiments or examples. This repetition is for simplicity and clarity, rather than to represent the relationship between the different embodiments and/or examples discussed.

Further, spatially relative terms, such as “above,” “upper,” “beneath,” “below,” “lower,” left,” “right,” and the like, may be used herein for ease of description to describe one element or feature's relationship to another element(s) or feature(s) as illustrated in the figures. Therefore, spatially relative terms are intended to illustrate rather than limit this disclosure. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of the present disclosure, the terms regarding disposing or connecting such as “on,” “connected to,” “coupled to”, or other similar terms, unless specifically defined, may mean that two components are in direct contact, or mean that two components are not in direct contact which includes the case where another component is interposed between them. The terms regarding disposing or connecting may also include the case where both structures are movable or both structures are fixed.

In addition, in the specification or the claims, ordinal numbers such as “first”, “second”, and other similar terms are used to name different components or distinguish different embodiments or scopes, not to limit the upper or lower limit of the number of components, nor to limit the manufacturing sequence of components or disposing sequence of components.

Here, the terms “about”, “approximately”, “substantially” usually mean within 10%, within 5%, or within 3%, within 2%, within 1% or within 0.5% of a given value or range. Here, the given value is an approximate number. That is, in the absence of a specific description of “about”, “approximately”, “substantially”, the meaning of “about”, “approximately”, “substantially” may still be implied.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of the present disclosure and will not be interpreted in an idealized or overly formal sense unless expressly so defined herein.

Different embodiments disclosed below may reuse the same reference symbols and/or labels. These repetitions are for the purpose of simplicity and clarity and are not intended to limit the specific relationship between the various embodiments and/or structures discussed below. It is understood that additional steps can be provided before, during, and after the steps of method, and some of the steps described can be replaced or eliminated for other embodiments of the method.

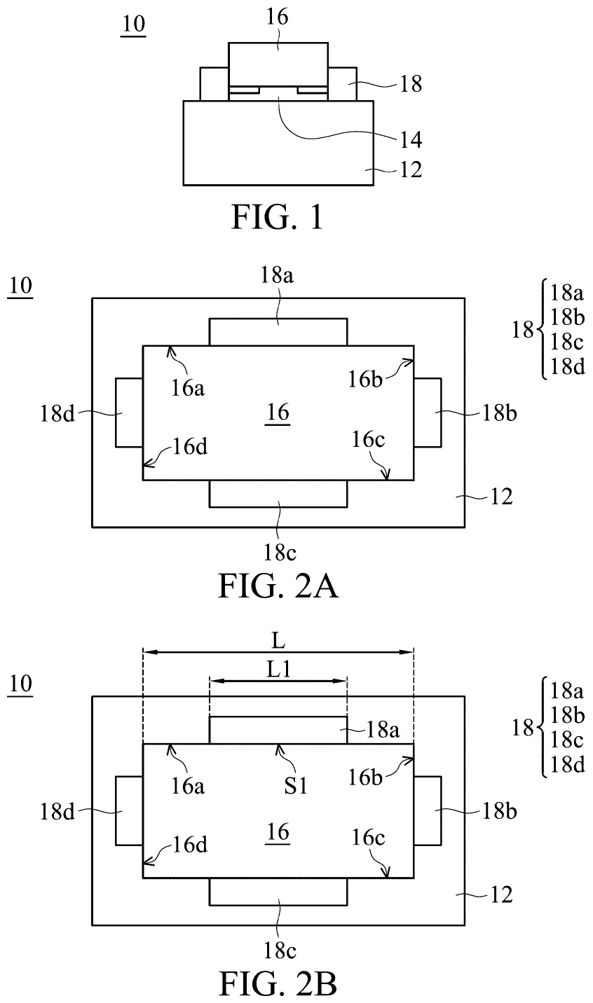

FIG. 1 illustrates a cross-sectional view of a laser transfer structure 10 according to some embodiments of the present disclosure.

In some embodiments, as shown in FIG. 1, the laser transfer structure 10 may include a carrier 12, a release layer 14, a chip 16, and a plurality of photoresist structures 18. The release layer 14 is disposed on the carrier 12. The chip 16 is disposed on the release layer 14. The photoresist structures 18 are disposed on the carrier 12 and surround the chip 16.

In some embodiments, the carrier 12 may be used as a donor substrate during a laser-transfer process. In some embodiments, the photoresist structures 18 may be used as a ballistic layer during a laser-transfer process. In some embodiments, in a laser-transfer process, the photoresist structures as the ballistic layer surrounding the chip can suppress the lateral kinetic energy of the chip and increase the lateral friction with the chip to stabilize the chip as it falls. When the chip falls from the carrier, the stability and collimation of the chip towards an acceptor substrate can be maintained, thereby reducing chip-flip rate and improving the accuracy of chip falling onto the acceptor substrate.

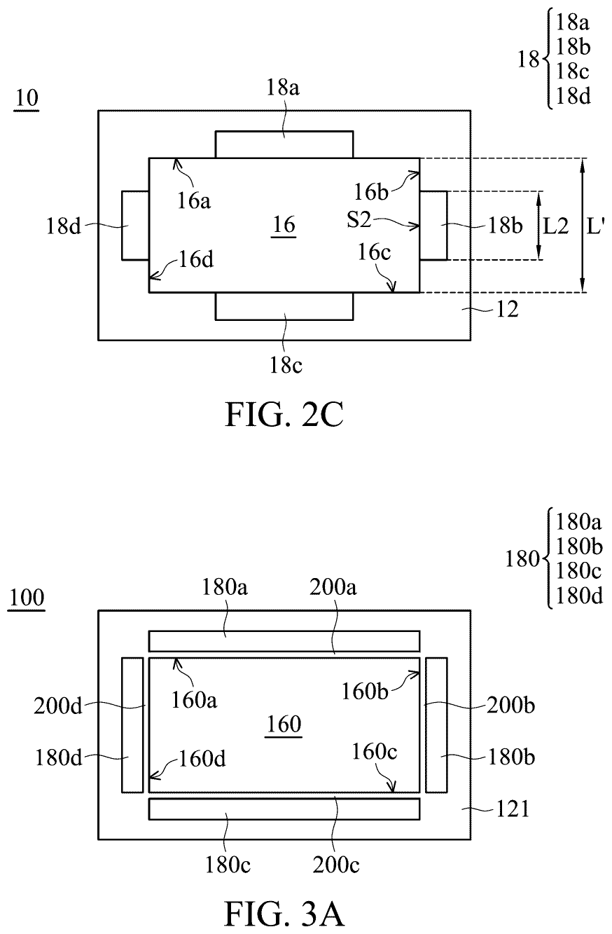

FIG. 2A illustrates a top view of a laser transfer structure 10 according to some embodiments of the present disclosure.

In some embodiments, as shown in FIG. 2A, the laser transfer structure 10 may include a carrier 12, a chip 16, and a plurality of photoresist structures 18. The chip 16 is disposed on the carrier 12. The photoresist structures 18 are disposed on the carrier 12 and surround the chip 16. In some embodiments, the chip 16 may include a rectangular shape, including a first side 16a, a second side 16b, a third side 16c, and a fourth side 16d. In some embodiments, the photoresist structures 18 may be separate from each other and surround the chip 16. In some embodiments, the photoresist structures 18 may include a first photoresist structure 18a, a second photoresist structure 18b, a third photoresist structure 18c, and a fourth photoresist structure 18d corresponding to the first side 16a, the second side 16b, the third side 16c, and the fourth side 16d of the chip 16 respectively. In some embodiments, one of the photoresist structures 18 may be in contact with the chip 16; for example, the first photoresist structure 18a, the second photoresist structure 18b, the third photoresist structure 18c, or the fourth photoresist structure 18d is in contact with the corresponding side of the chip 16. In some embodiments, all of the photoresist structures 18 may be in contact with the chip 16; for example, the first photoresist structure 18a, the second photoresist structure 18b, the third photoresist structure 18c, and the fourth photoresist structure 18d are in contact with the corresponding sides of the chip 16 respectively, as shown in FIG. 2A.

FIG. 2B illustrates a top view of a laser transfer structure 10 according to some embodiments of the present disclosure to further illustrate the dimensional relationship between a chip and photoresist structures.

The laser transfer structure 10 of FIG. 2B is similar to that of FIG. 2A, for example, the photoresist structures 18 include the first photoresist structure 18a, the second photoresist structure 18b, the third photoresist structure 18c, and the fourth photoresist structure 18d corresponding to the first side 16a, the second side 16b, the third side 16c, and the fourth side 16d of the chip 16 and in contact with the corresponding sides of the chip 16 respectively. Here, the dimensional relationship between the chip 16 and the first photoresist structure 18a is taken as an example for illustration.

As shown in FIG. 2B, there is a first contact surface S1 between the first photoresist structure 18a and the first side 16a of the chip 16. In some embodiments, the first contact surface S1 has a first length L1, and the ratio of the first length L1 to the length L of the first side 16a of the chip 16 is in a range from about 0.5:1 to about 1:1. In some embodiments, as shown in FIG. 2B, the dimensional relationship between the chip 16 and the third photoresist structure 18c is similar to that between the chip 16 and the first photoresist structure 18a, and different from those between the chip 16 and the second photoresist structure 18b and the fourth photoresist structure 18d.

FIG. 2C illustrates a top view of a laser transfer structure 10 according to some embodiments of the present disclosure to further illustrate the dimensional relationship between a chip and photoresist structures.

The laser transfer structure 10 of FIG. 2C is similar to that of FIG. 2A, for example, the photoresist structures 18 include the first photoresist structure 18a, the second photoresist structure 18b, the third photoresist structure 18c, and the fourth photoresist structure 18d corresponding to the first side 16a, the second side 16b, the third side 16c, and the fourth side 16d of the chip 16 and in contact with the corresponding sides of the chip 16 respectively. Here, the dimensional relationship between the chip 16 and the second photoresist structure 18b is taken as an example for illustration.

As shown in FIG. 2C, there is a second contact surface S2 between the second photoresist structure 18b and the second side 16b of the chip 16. In some embodiments, the second contact surface S2 has a second length L2, and the ratio of the second length L2 to the length L′ of the second side 16b of the chip 16 is in a range from about 0.5:1 to about 1:1. In some embodiments, as shown in FIG. 2C, the dimensional relationship between the chip 16 and the fourth photoresist structure 18d is similar to that between the chip 16 and the second photoresist structure 18b, and different from those between the chip 16 and the first photoresist structure 18a and the third photoresist structure 18c. In some embodiments, the second side 16b of the chip 16 is perpendicular to the first side 16a of the chip 16.

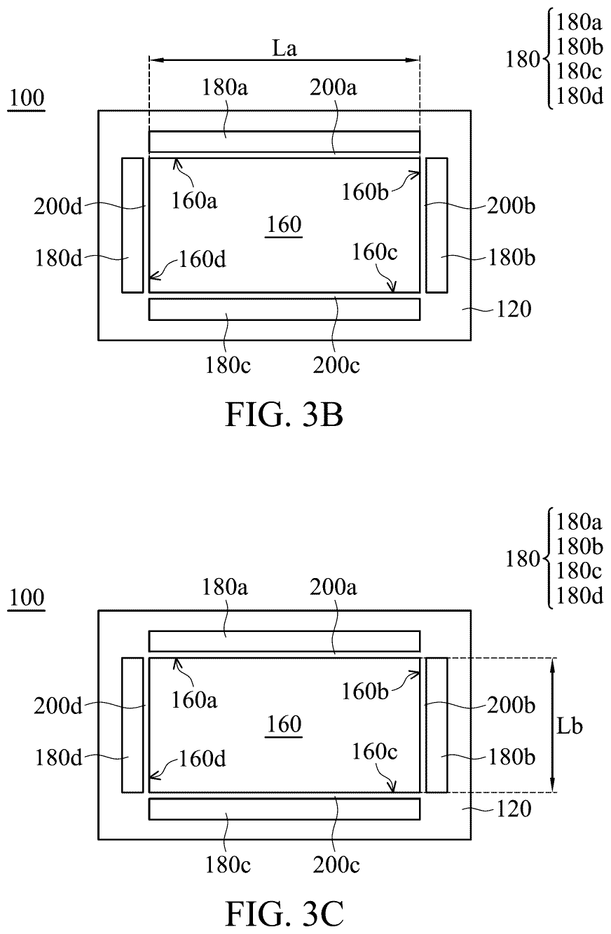

FIG. 3A illustrates a top view of a laser transfer structure 100 according to some embodiments of the present disclosure.

In some embodiments, as shown in FIG. 3A, the laser transfer structure 100 may include a carrier 121, a chip 160 and a plurality of photoresist structures 180. The chip 160 is disposed on the carrier 121. The photoresist structures 180 are disposed on the carrier 121 and surround the chip 160. In some embodiments, the chip 160 may include a rectangular shape, including a first side 160a, a second side 160b, a third side 160c, and a fourth side 160d. In some embodiments, the photoresist structures 180 may be separate from each other and surround the chip 160. In some embodiments, the photoresist structures 180 may include a first photoresist structure 180a, a second photoresist structure 180b, a third photoresist structure 180c, and a fourth photoresist structure 180d corresponding to the first side 160a, the second side 160b, the third side 160c, and the fourth side 160d of the chip 160 respectively. In some embodiments, there is a gap between the chip 160 and one of the photoresist structures 180; for example, there is a gap between the first photoresist structure 180a, the second photoresist structure 180b, the third photoresist structure 180c, or the fourth photoresist structure 180d and the corresponding side of the chip 160. In some embodiments, there are gaps (e.g., 200a, 200b, 200c, and 200d) between the chip 160 and all of the photoresist structures 180; for example, there are gaps (e.g., a first gap 200a, a second gap 200b, a third gap 200c, and a fourth gap 200d) between the first photoresist structure 180a, the second photoresist structure 180b, the third photoresist structure 180c, and the fourth photoresist structure 180d and the corresponding sides of the chip 160 respectively, as shown in FIG. 3A.

FIG. 3B illustrates a top view of a laser transfer structure 100 according to some embodiments of the present disclosure to further illustrate the dimensional relationship between a chip and a gap.

The laser transfer structure 100 of FIG. 3B is similar to that of FIG. 3A, for example, the photoresist structures 180 includes the first photoresist structure 180a, the second photoresist structure 180b, the third photoresist structure 180c, and the fourth photoresist structure 180d corresponding to the first side 160a, the second side 160b, the third side 160c, and the fourth side 160d of the chip 160 respectively, and there are gaps (e.g., the first gap 200a, the second gap 200b, the third gap 200c, and the fourth gap 200d) between the first photoresist structure 180a, the second photoresist structure 180b, the third photoresist structure 180c, and the fourth photoresist structure 180d and the corresponding sides of the chip 160 respectively. Here, the dimensional relationship between the chip 160 and the first gap 200a is taken as an example for illustration.

As shown in FIG. 3B, there is the first gap 200a between the first photoresist structure 180a and the first side 160a of the chip 160. In some embodiments, the ratio of the first gap 200a to a length La of the first side 160a of the chip 160 is in a range from about 0.01:10 to about 1:10. In some embodiments, as shown in FIG. 3B, the dimensional relationship between the chip 160 and the second gap 200b, the third gap 200c, and the fourth gap 200d is similar to that between the chip 160 and the first gap 200a.

FIG. 3C illustrates a top view of a laser transfer structure 100 according to some embodiments of the present disclosure to further illustrate the dimensional relationship between a chip and a gap.

The laser transfer structure 100 of FIG. 3C is similar to that of FIG. 3A, for example, the photoresist structures 180 includes the first photoresist structure 180a, the second photoresist structure 180b, the third photoresist structure 180c, and the fourth photoresist structure 180d corresponding to the first side 160a, the second side 160b, the third side 160c, and the fourth side 160d of the chip 160 respectively, and there are gaps (e.g., the first gap 200a, the second gap 200b, the third gap 200c, and the fourth gap 200d) between the first photoresist structure 180a, the second photoresist structure 180b, the third photoresist structure 180c, and the fourth photoresist structure 180d and the corresponding sides of the chip 160 respectively. Here, the dimensional relationship between the chip 160 and the second gap 200b is taken as an example for illustration.

As shown in FIG. 3C, there is the second gap 200b between the second photoresist structure 180b and the second side 160b of the chip 160. In some embodiments, the ratio of the second gap 200b to a length Lb of the second side 160b of the chip 160 is in a range from about 0.01:10 to about 1:10. In some embodiments, as shown in FIG. 3C, the dimensional relationship between the chip 160 and the first gap 200a, the third gap 200c, and the fourth gap 200d is similar to that between the chip 160 and the second gap 200b.

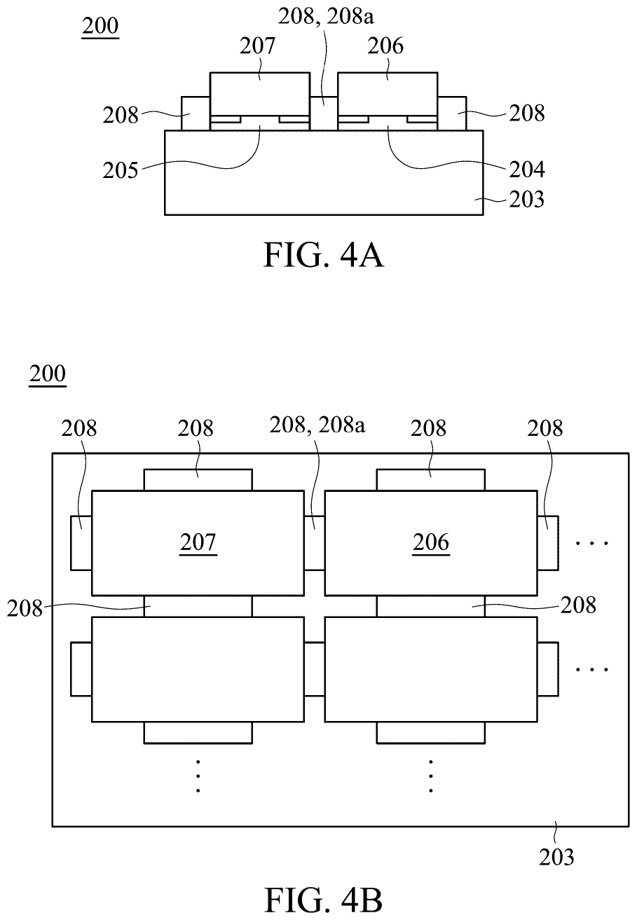

Referring to FIGS. 4A and 4B, a laser transfer structure 200 is provided. FIG. 4A illustrates a cross-sectional view of the laser transfer structure 200 according to some embodiments of the present disclosure. FIG. 4B illustrates a top view of the laser transfer structure 200 according to some embodiments of the present disclosure. In some embodiments, the second side 160b of the chip 160 is perpendicular to the first side 160a of the chip 160.

In some embodiments, as shown in FIGS. 4A and 4B, the laser transfer structure 200 may include a carrier 203, a first release layer 204, a second release layer 205, a first chip 206, a second chip 207, and a plurality of photoresist structures 208. The first release layer 204 and the second release layer 205 are disposed on the carrier 203. The first chip 206 is disposed on the first release layer 204. The second chip 207 adjacent to the first chip 206 is disposed on the second release layer 205. The photoresist structures 208 are disposed on the carrier 203, surround and contact the first chip 206 and the second chip 207 respectively. Specifically, one of the photoresist structures 208, for example, the photoresist structure 208a, is in contact with the first chip 206 and the second chip 207 at the same time.

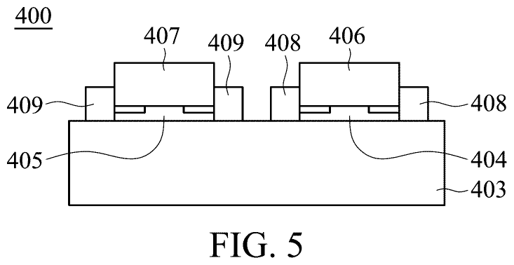

FIG. 5 illustrates a cross-sectional view of a laser transfer structure 400 according to some embodiments of the present disclosure.

In some embodiments, as shown in FIG. 5, the laser transfer structure 400 may include a carrier 403, a first release layer 404, a second release layer 405, a first chip 406, a second chip 407, a plurality of first photoresist structures 408, and a plurality of second photoresist structures 409. The first release layer 404 and the second release layer 405 are disposed on the carrier 403. The first chip 406 is disposed on the first release layer 404. The second chip 407 adjacent to the first chip 406 is disposed on the second release layer 405. The first photoresist structures 408 are disposed on the carrier 403, surround and contact the first chip 406. The second photoresist structures 409 are disposed on the carrier 403, surround and contact the second chip 407. Specifically, the second photoresist structures 409 are separate from the first photoresist structures 408.

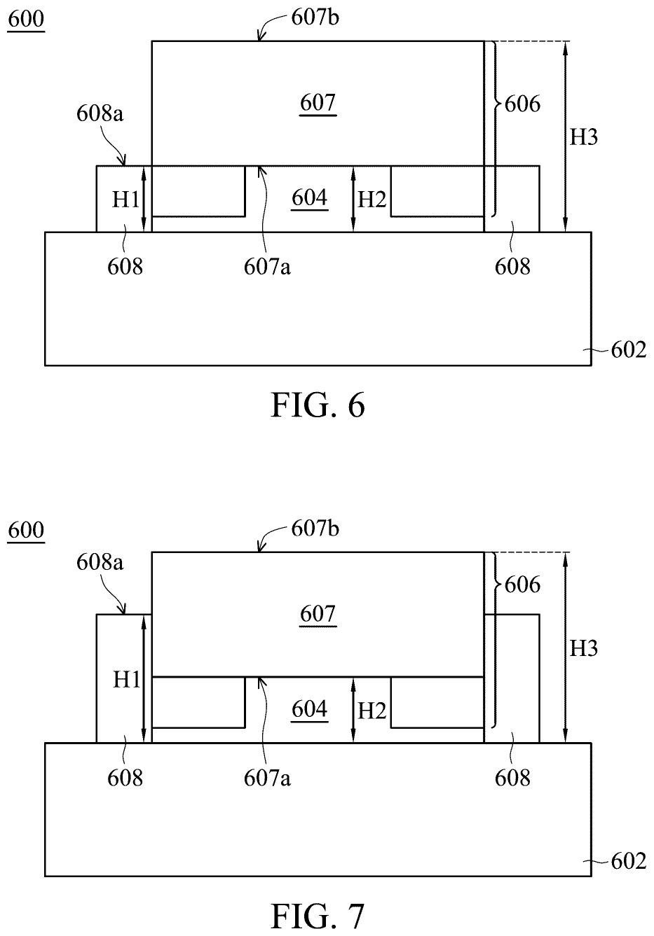

FIG. 6 illustrates a cross-sectional view of a laser transfer structure 600 according to some embodiments of the present disclosure to further illustrate the dimensional relationship between a chip and photoresist structures.

In some embodiments, as shown in FIG. 6, the laser transfer structure 600 may include a carrier 602, a release layer 604, a chip 606, and a plurality of photoresist structures 608. The release layer 604 is disposed on the carrier 602. The chip 606 is disposed on the release layer 604. The photoresist structures 608 are disposed on the carrier 602, surround and contact the chip 606. The chip 606 includes a substrate 607. The substrate 607 has a first surface 607a towards the carrier 602 and a second surface 607b opposite to the first surface 607a. In FIG. 6, the distance between the upper surface 608a of the photoresist structures 608 and the carrier 602 is defined as a first height H1. The distance between the first surface 607a of the substrate 607 and the carrier 602 is defined as a second height H2. The distance between the second surface 607b of the substrate 607 and the carrier 602 is defined as a third height H3. In some embodiments, the first height H1 is greater than the second height H2. In some embodiments, the first height H1 is equal to the second height H2, as shown in FIG. 6.

FIG. 7 illustrates a cross-sectional view of a laser transfer structure 600 according to some embodiments of the present disclosure to further illustrate the dimensional relationship between a chip and photoresist structures.

The laser transfer structure 600 of FIG. 7 is similar to that of FIG. 6, and the main difference between the two is the height of the photoresist structures. In FIG. 7, the first height H1 (i.e., the distance between the upper surface 608a of the photoresist structures 608 and the carrier 602) is greater than the second height H2 (i.e., the distance between the first surface 607a of the substrate 607 and the carrier 602) and less than the third height H3 (i.e., the distance between the second surface 607b of the substrate 607 and the carrier 602).

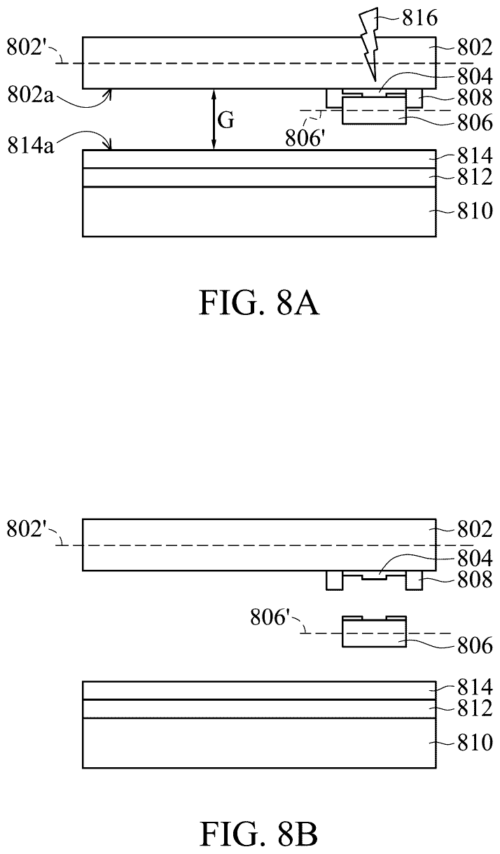

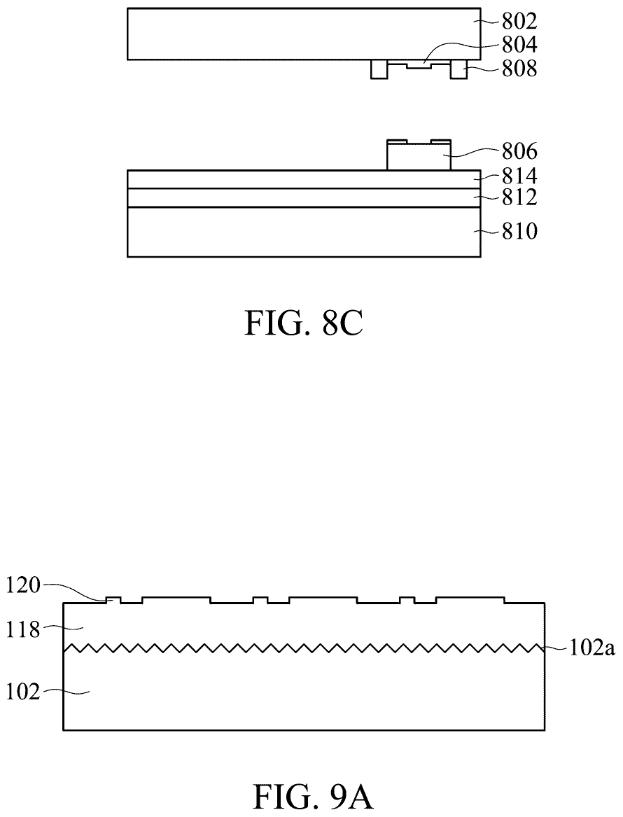

FIGS. 8A-8C respectively illustrate cross-sectional views of a laser transfer method according to some embodiments of the present disclosure.

First, in some embodiments, as shown in FIG. 8A, a first carrier 802 with a release layer 804, a chip 806, and a plurality of photoresist structures 808 disposed thereon is provided. The photoresist structures 808 surround and contact the chip 806. In some embodiments, there is a gap (not shown) between the chip 806 and one of the photoresist structures 808 (similar to the embodiment disclosed by FIG. 3A). A second carrier 810 with a buffer layer 812 and an adhesive layer 814 disposed thereon is provided. The second carrier 810 is opposite to the first carrier 802. In some embodiments, as shown in FIG. 8A, there is a gap G between the surface 802a of the first carrier 802 and the surface 814a of the adhesive layer 814, which ranges from about 70 μm to about 100 μm. Before falling, the transverse axis 806′ of the chip 806 is parallel to the transverse axis 802′ of the first carrier 802.

Next, in some embodiments, a laser radiation 816 is performed. The chip 806 then leaves the first carrier 802 and falls downward, while the release layer 804 and the photoresist structures 808 are left on the first carrier 802, as shown in FIG. 8B. In some embodiments, the energy of the laser radiation 816 is in a range from about 80 mJ to about 120 mJ. During the falling process, the transverse axis 806′ of the chip 806 is still parallel to the transverse axis 802′ of the first carrier 802.

When the chip 806 lands on the second carrier 810, the laser transfer method is completed, as shown in FIG. 8C.

The accuracy of the chip falling from the first carrier to the second carrier dominates the chip transfer yield, so the stability of the chip falling brought by the photoresist structures (i.e., the ballistic structure) significantly improves the chip transfer yield.

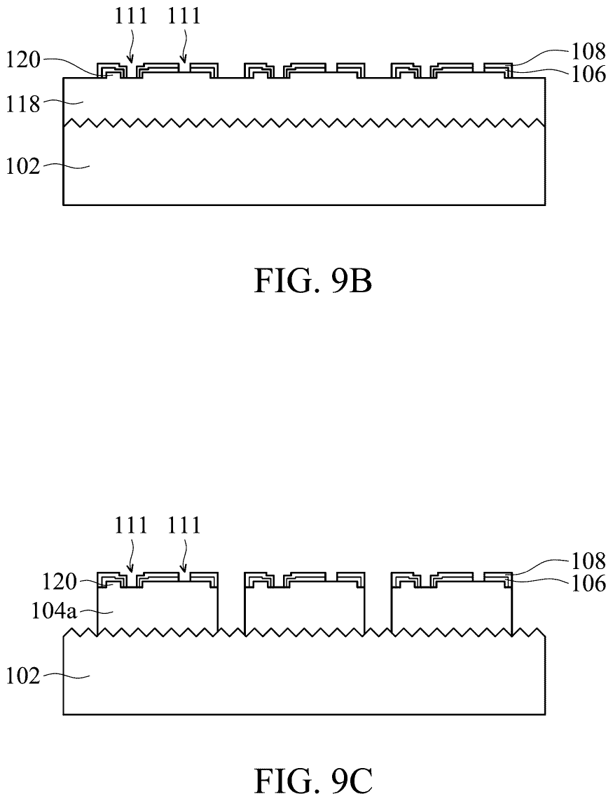

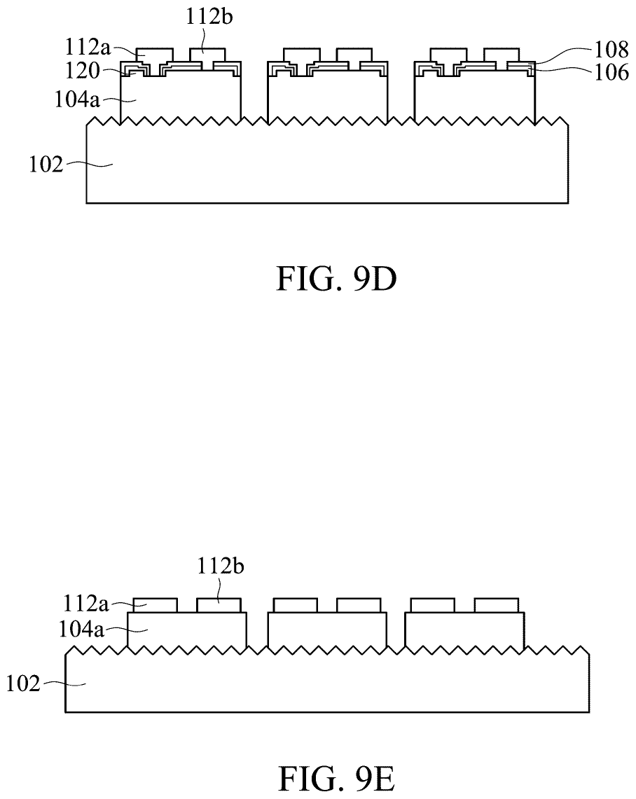

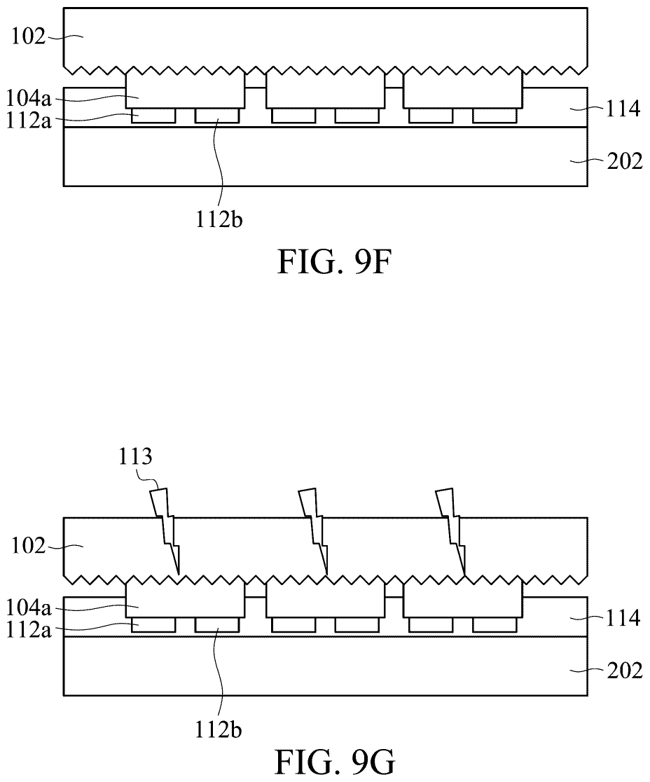

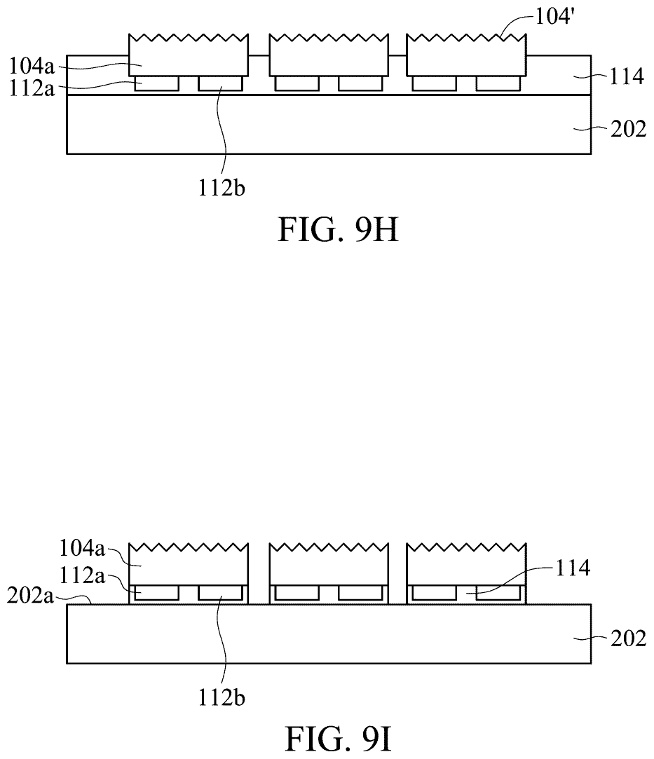

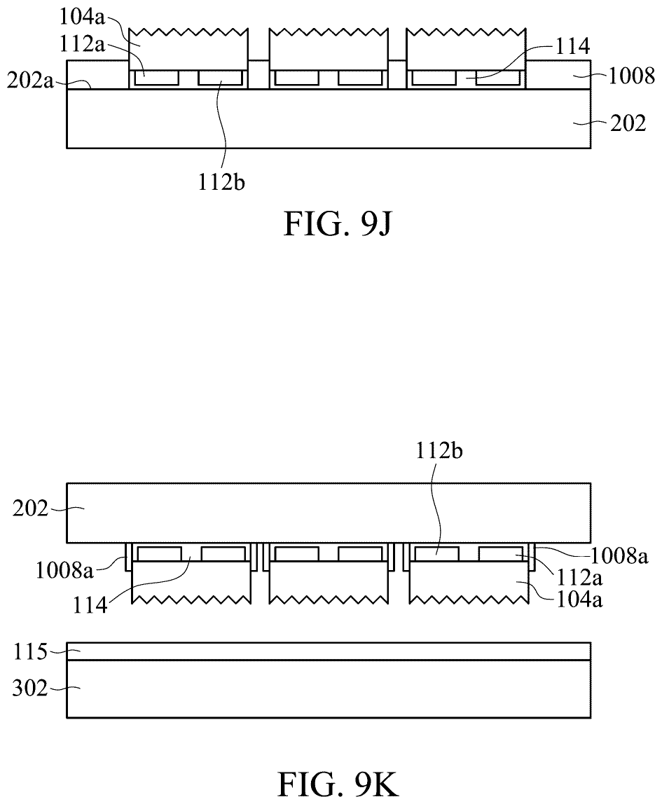

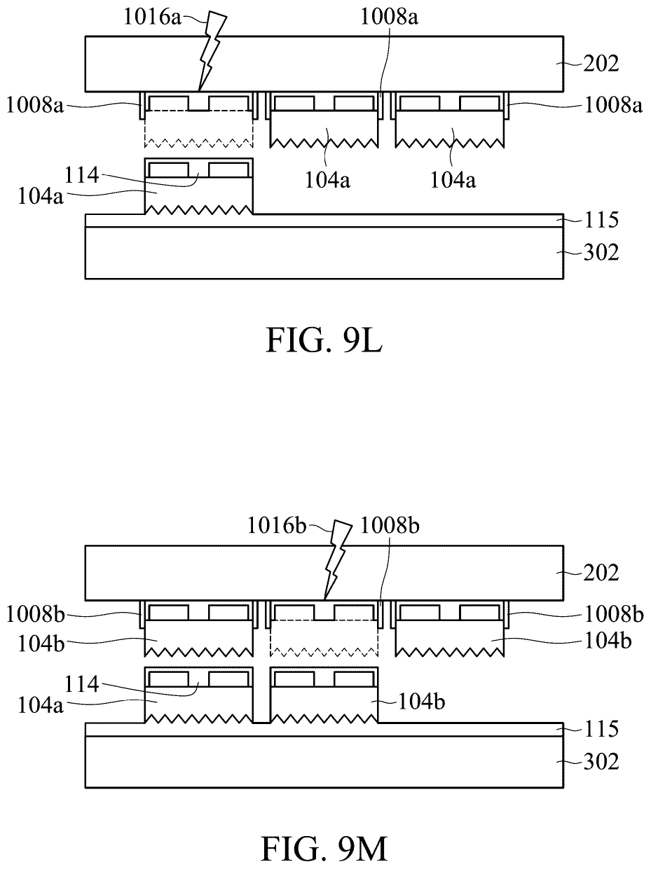

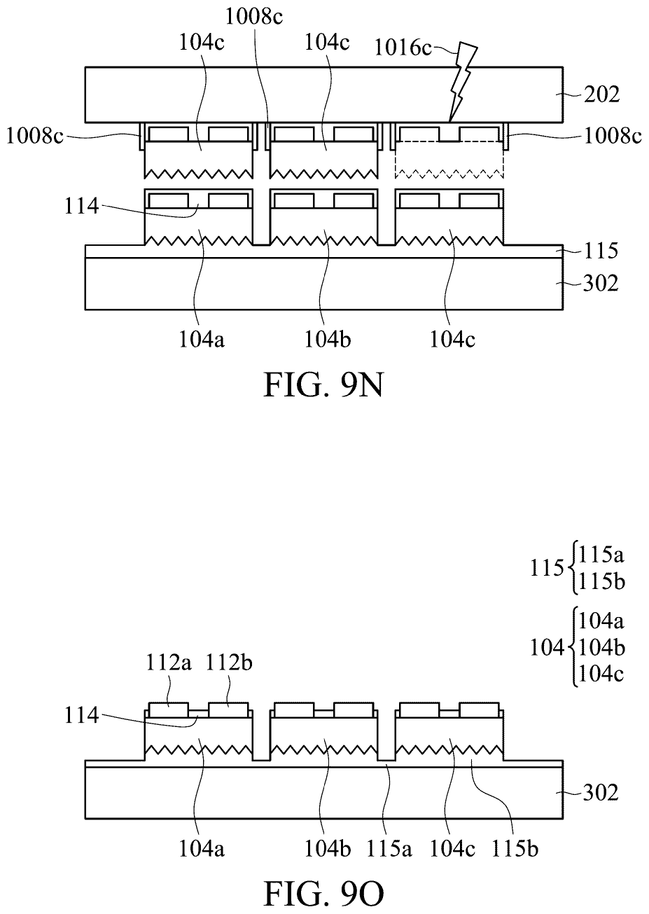

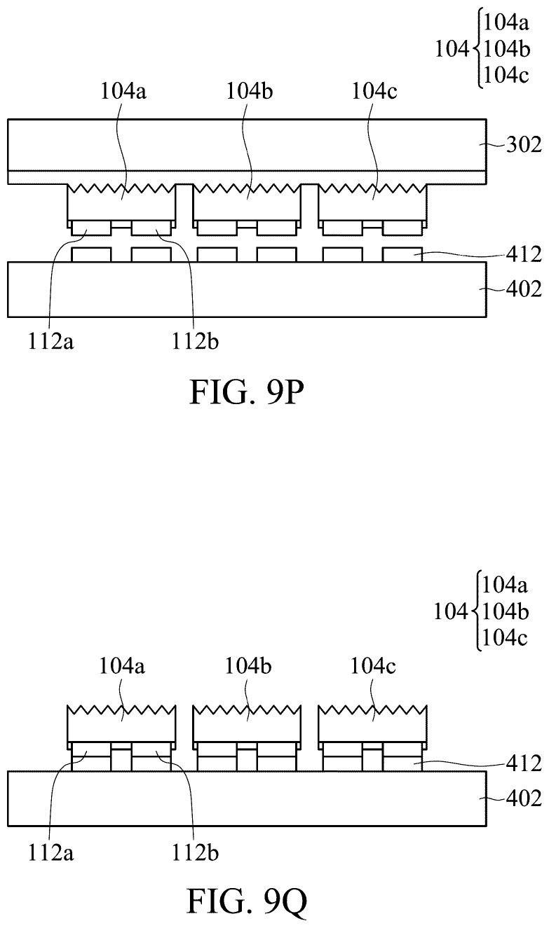

FIGS. 9A-9Q respectively illustrate cross-sectional views of a method for fabricating a display module according to some embodiments of the present disclosure.

In some embodiments, as shown in FIG. 9A, an epitaxial semiconductor layer 118 is formed on a semiconductor substrate 102. In some embodiments, before forming the epitaxial semiconductor layer 118, a roughening process may be performed on the semiconductor substrate 102 to form a periodically roughened surface 102a. In some embodiments, a patterned sapphire substrate (PSS) technique is used to form a patterned substrate to increase light extraction efficiency. For example, a patterned substrate may be formed by photolithography and etching processes. During a photolithography process, a photoresist layer (not shown) is first applied to the semiconductor substrate 102 by, for example, spin coating. Then, the photoresist layer is exposed according to a patterned mask and is developed to form periodic patterns in the photoresist layer. The photoresist layer with the periodic patterns can be used as an etch mask to pattern the semiconductor substrate 102. The patterned photoresist layer is then used to protect portions of the surfaces of the semiconductor substrate 102, while a plurality of cavities is formed by an etching process that etches into the surface of the semiconductor substrate 102 in unprotected regions, thereby leaving the periodic roughened surface 102a. Then, the photoresist layer is removed. In some examples, the periodic roughened surface 102a is formed by a dry etch process, such as reactive ion etching (RIE), a wet etch, or a combination thereof.

It should be noted that the roughening process described herein is optional, and it may not be performed, or the roughening process may be performed on an LED chip in a subsequent process. In some embodiments, the epitaxial semiconductor layer 118 includes a first-type semiconductor layer, a light-emitting layer, and a second-type semiconductor layer sequentially formed on the semiconductor substrate 102. For example, the first-type semiconductor layer and the second-type semiconductor layer may be different types of semiconductor materials. For example, the first-type semiconductor layer is gallium nitride with n-type conductivity (n-GaN), and the second-type semiconductor layer is gallium nitride with p-type conductivity (p-GaN), and vice versa. Other III-V compounds may be used, such as indium nitride (InN), aluminum nitride (AIN), indium gallium nitride (InₓGa₍₁₋ₓ₎N), aluminum gallium nitride (AlₓGa(₁₋ₓ)N), or aluminum indium gallium nitride (AlₓIn_{y}Ga_{(1-x-y)}N), wherein 0<x≤1, 0<y≤1, and 0≤x+y≤1. The light-emitting layer may have a multiple quantum well (MQW) structure composed of semiconductor materials. The light-emitting layer may include other suitable light-emitting materials, and is not limited thereto. In some embodiments, the method for forming the epitaxial semiconductor layer 118 may include an epitaxial growth process, such as chemical vapor deposition (CVD), metal-organic chemical vapor deposition (MOCVD), molecular beam epitaxy (MBE), hydride vapor phase epitaxy (HVPE), liquid phase epitaxy (LPE) or other suitable CVD methods.

Still referring to FIG. 9A, then, a patterned mesa structure 120 is formed on the epitaxial semiconductor layer 118 by a patterning process to define the feature regions to be formed. The patterning process described above may include photolithography and etching processes, which are similar to the patterning process described above, and are not repeated herein for brevity.

In some embodiments, as shown in FIG. 9B, a first reflection layer 106 is formed on the mesa structure 120. The first reflection layer 106 has a high reflectivity for a waveband of light emitted from the LED chip, for example, greater than 90%, to reflect the waveband of the light emitted from the LED chip so as to increase the EQE. In some embodiments, the first reflection layer 106 may be a distributed Bragg reflector (DBR). In some embodiments, the DBR layer may include a periodic structure formed by alternating combination of two material layers with different refractive index. In some embodiments, the material of the DBR layer may include an insulator. For example, the material of the DBR layer may include silicon oxide (SiO₂), titanium oxide (TiO₂), tantalum oxide (Ta₂O₅), aluminum oxide (Al₂O₃), or silicon nitride (Si₃N₄). The thickness of each DBR layer is related to the wavelength of incident light. When the product of the refractive index and the optical thickness of each DBR layer is equal to a quarter of the wavelength of the incident light, the optical path difference between the incident light and the reflected light is equal to an integral multiple of the incident light wavelength (nλ, n=1,2,3 . . . ), and result in constructive interference. The light may not penetrate the DBR layer. Due to the above principles and material properties, the DBR layer may reflect the waveband of the light emitted from the LED chip and hence increase the EQE. In some embodiments, the higher the number of the DBR layers, the more significant the light reflection. In some embodiments, the thickness of the first reflection layer 106 may be controlled in the range from 0.1 μm to 4 μm. In some embodiments, the thickness of the first reflection layer 106 may be controlled in the range from 0.6 μm to 2 μm. In some embodiments, the thickness of the first reflection layer 106 may be 0.1 μm, 0.2 μm, 0.3 μm, 0.4 μm, 0.5 μm, 0.6 μm, 0.7 μm, 0.8 μm, 0.9 μm, 1 μm, 1.2 μm, 1.5 μm, 1.7 μm, 2 μm, 2.2 μm, 2.5 μm, 2.7 μm, 3 μm, 3.2 μm, 3.5 μm, 3.7 μm, or 4 μm.

Then, a second reflection layer 108 is formed on the first reflection layer 106. The second reflection layer 108 has a high reflectivity, e.g., greater than 90%, for a laser transfer technique used in a process of transferring LED chips; therefore, the second reflection layer 108 may reflect the laser used in the subsequent selective laser transfer technique, to prevent the laser-induced thermal damage to the LED chips. In some embodiments, the second reflection layer 108 may be a DBR layer with a different thickness from that of the first reflection layer 106. In some embodiments, the material of the DBR layer of the second reflection layer 108 may be similar to that of the first reflection layer 106. In some embodiments, the material of the DBR layer of the second reflection layer 108 may be the same to that of the first reflection layer 106 to reduce the difficulties of the manufacturing process. In some embodiments, the material of the DBR layer of the second reflection layer 108 may be different from that of the first reflection layer 106. In some embodiments, the higher the number of layers in the second reflection layer 108, the more significant the light reflection. In some embodiments, the thickness of the second reflection layer 108 can be controlled in the range from 0.1 μm to 4 μm. In some embodiments, the thickness of the second reflection layer 108 may be controlled in the range from 0.6 μm to 2 μm. In some embodiments, the thickness of the second reflection layer 108 may be 0.1 μm, 0.2 μm, 0.3 μm, 0.4 μm, 0.5 μm, 0.6 μm, 0.7 μm, 0.8 μm, 0.9 μm, 1 μm, 1.2 μm, 1.5 μm, 1.7 μm, 2 μm, 2.2 μm, 2.5 μm, 2.7 μm, 3 μm, 3.2 μm, 3.5 μm, 3.7 μm, or 4 μm. In some embodiments, the thickness of the second reflection layer 108 is less than the thickness of the first reflection layer 106.

In FIG. 9B, the first reflection layer 106 is configured to reflect the waveband of the light emitted from the LED chips. The second reflection layer 108 is configured to reflect the laser waveband. The wavelength of the laser waveband is, for example, less than 420 nm.

Then, the first reflection layer 106 and the second reflection layer 108 are patterned to form recesses 111 extending through the first reflection layer 106 and the second reflection layer 108 to expose a portion of the epitaxial semiconductor layer 118, as shown in FIG. 9B. The recesses 111 can be used to form electrodes of LED chips in a subsequent process. The patterning process may be similar to the patterning process described above, and is not repeated herein for brevity.

In some embodiments, as shown in FIG. 9C, the epitaxial semiconductor layer 118 is etched to form LED chips 104a spaced apart from each other. The etching process may include dry etching, such as reactive ion etching (RIE), wet etching, or a combination thereof.

In some embodiments, as shown in FIG. 9D, a first electrode 112a and a second electrode 112b penetrating through the first reflection layer 106 and the second reflection layer 108 are formed, wherein the first electrode 112a and the second electrode 112b are in physical contact with the LED chip 104a. In some embodiments, the material of the first electrode 112a and the second electrode 112b may be metal or a metal alloy. For example, the metal materials of the first electrode 112a and the second electrode 112b may include copper (Cu), aluminum (Al), indium (In), tin (Sn), gold (Au), platinum (Pt), zinc (Zn), silver (Ag), titanium (Ti), nickel (Ni), or a combination thereof. In some embodiments, the first electrode 112a and the second electrode 112b may be formed by the deposition process, such as low-pressure chemical vapor deposition (LPCVD), plasma chemical vapor deposition (PECVD), physical vapor deposition (PVD), atomic layer deposition (ALD), or other suitable deposition processes. Subsequently, the electrode layer may be patterned by photolithography and etching processes, as shown in FIG. 9D. For example, the patterning process may be similar to the patterning process described above, and are not repeated herein for brevity.

For the sake of brevity, FIG. 9D is simplified to FIG. 9E. In FIG. 9E, the plurality of LED chips 104a are formed on the semiconductor substrate 102 spaced apart from each other. Each LED chip 104a has the first electrode 112a (e.g., a positive electrode) and the second electrode 112b (e.g., a negative electrode). In some embodiments, the first electrode 112a is a negative electrode, and the second electrode 112b is a positive electrode. The first electrode 112a and the second electrode 112b are disposed on the same side of the LED chip 104a facing away from the semiconductor substrate 102 (may also referred to as the front side of the LED chip 104a). In some embodiments, the semiconductor substrate 102 may be a sapphire substrate, a silicon substrate, a silicon carbide substrate, or a ceramic substrate.

In some embodiments, there is a single reflection layer, for example, the first reflection layer 106, on the mesa structure 120. In some embodiments, the LED chips 104a includes a single reflection layer (e.g., the first reflection layer 106). In some embodiments, the LED chips 104a include the first reflection layer 106 and do not include the second reflection layer 108. In some embodiments, the LED chips 104a include one type of reflection layer.

In some embodiments, as shown in FIG. 9F, first, a carrier 202 with a first adhesion layer 114 (also referred to as a glue) is provided. In some embodiments, the material of the carrier 202 may include a plastic substrate or a glass substrate. In some embodiments, the material of the carrier 202 may include a silicon substrate, a sapphire substrate, or a substrate made of another suitable material for the carrier 202. In some embodiments, the first adhesion layer 114 may be UV glue which can react with the laser used later. In some embodiments, the first adhesion layer 114 decomposes after absorbing the applied laser such that the LED chips 104a are peeled off from the first adhesion layer 114. In some embodiments, the waveband of the laser used is less than 420 nm. For example, the wavelength of the waveband may be 248, 260, 280, or 355 nm.

In some embodiments, the first adhesion layer 114 may be formed on the carrier 202 by spin coating. Next, the structures shown in FIG. 9E are bonded to the first adhesion layer 114 on the carrier 202. In some embodiments, the first adhesion layer 114 fills into the gaps between the LED chips 104a, attaches to parts of the sidewalls of the LED chips 104a, and covers the first electrode 112a and the second electrode 112b, but is not in direct contact with the semiconductor substrate 102, as shown in FIG. 9F. In some embodiments, the first adhesion layer 114 covers 100% of the top surface and 80% of the side surface of the LED chips 104a. In other embodiments, the first adhesion layer 114 attaches to the overall top surface and side surface of the LED chips 104a, and directly contacts the semiconductor substrate 102 (not shown).

In some embodiments, as shown in FIG. 9G, the semiconductor substrate 102 is removed by an LLO process (laser lift-off) 113 and the LED chips 104a are transferred to the carrier 202. In some embodiments, the semiconductor substrate 102 is removed by the fully LLO process and the LED chips 104a are transferred to the carrier 202. In some embodiments, the LLO process 113 is applied to the semiconductor substrate 102 to remove the semiconductor substrate 102. In some embodiments, the wavelength of the laser used in the LLO process 113 is below 420 nm, for example, the wavelength is 248, 260, 280, or 355 nm. In some embodiments, the material of the LED chips 104a may absorb all the laser energy used in the laser LLO process to avoid the LED chips 104a from being damaged by the laser. In some embodiment, the LED chips 104a include a III-V compound (e.g., gallium nitride), the III-V compound may absorb all the laser energy at the interface with the semiconductor substrate 102 to prevent LED dies chips from being damaged by laser and to improve the yield of the light-emitting device.

In some embodiments, as shown in FIG. 9H, since the semiconductor substrate 102 has the periodically roughened surface 102a, the LED chip 104a also has a periodically roughened surface 104′ at the interface with the semiconductor substrate 102. After the LLO process, the periodically roughened surface 104′ of the LED chip 104a may be exposed to increase the light extraction efficiency of the LED chip 104a. In some embodiments, the LED chip 104a has the roughened surface 104′ having periodically arranged concave and convex textures. In some embodiments, the LED chip 104a includes a non-periodic roughened surface 104′.

In some embodiments, as shown in FIG. 9I, the first adhesion layer 114 between the sidewalls of the LED chips 104a is etched to expose the upper surface 202a of the carrier 202, and the LED chips 104a are separated in favor of subsequent selective transfer of the LED chips 104a. Hence, the difficulties of selective transferring caused by the first adhesion layer 114 remaining between each LED chip 104a are reduced. The etching process may include dry etching such as reactive ion etching (RIE), wet etching, or a combination thereof.

In some embodiments, as shown in FIG. 9J, a photoresist layer 1008 is formed on the carrier 202 and filled between the LED chips 104a by, for example, spin coating. Next, the photoresist layer 1008 is etched to form a plurality of patterned first photoresist structures 1008a, exposing a part of the carrier 202, as shown in FIG. 9K. The etching process may include dry etching such as inductively coupled plasma (ICP) etching.

In some embodiments, as shown in FIG. 9K, each LED chip 104a is surrounded by the first photoresist structures 1008a and in contact with the first photoresist structures 1008a. A second carrier 302 with a second adhesion layer 115 thereon is provided. In some embodiments, the material of the second carrier 302 may include a plastic substrate or a glass substrate. In some embodiments, the material of the second carrier 302 may include a silicon substrate or a sapphire substrate, or a substrate made of another suitable material for the second carrier 302. In some embodiments, the second adhesion layer 115 may be an elastic polymer material with viscosity. In some embodiments, the elastic polymer material with viscosity may include a siloxane polymer based material, such as polydimethylsiloxane (PDMS). In some embodiments, the second adhesion layer 115 may be formed by spin coating.

In some embodiments, as shown in FIG. 9L, the LED chip 104a is transferred from the carrier 202 to the second carrier 302 using the first laser radiation 1016a, while the first photoresist structures 1008a, which surround the LED chip 104a transferred to the second carrier 302, are left on the carrier 202. The LED chip 104a is transferred from the carrier 202 to the second carrier 302 by selective transfer of the LED chips 104a. The LED chip 104a is transferred from the carrier 202 to the second carrier 302 by the selective laser transfer process. In some embodiments, the energy of the first laser radiation 1016a is in a range from about 80 mJ to about 120 mJ.

In some embodiments, as shown in FIG. 9M, the carrier 202 with a plurality of LED chips 104b and a plurality of second photoresist structures 1008b disposed thereon is provided. Each LED chip 104b is surrounded by the second photoresist structures 1008b and in contact with the second photoresist structures 1008b. The second carrier 302 with the LED chip 104a, opposite to the carrier 202, is provided. The LED chip 104b is transferred from the carrier 202 to the second carrier 302 using the second laser radiation 1016b, while the second photoresist structures 1008b, which surround the LED chip 104b transferred to the second carrier 302, are left on the carrier 202. The LED chip 104b is transferred from the carrier 202 to the second carrier 302 by selective transfer of the LED chip 104b. The LED chip 104b is transferred from the carrier 202 to the second carrier 302 by the selective laser transfer process. In some embodiments, the energy of the second laser radiation 1016b is in a range from about 80 mJ to about 120 mJ.

In some embodiments, as shown in FIG. 9N, the carrier 202 with a plurality of LED chips 104c and a plurality of third photoresist structures 1008c disposed thereon is provided. Each LED chip 104c is surrounded by the third photoresist structures 1008c and in contact with the third photoresist structures 1008c. The second carrier 302 with the LED chips (104a and 104b), opposite to the carrier 202, is provided. The LED chip 104c is transferred from the carrier 202 to the second carrier 302 using the third laser radiation 1016c, while the third photoresist structures 1008c, which surround the LED chip 104c transferred to the second carrier 302, are left on the carrier 202. The LED chip 104c is transferred from the carrier 202 to the second carrier 302 by selective transfer of the LED chip 104c. The LED chip 104c is transferred from the carrier 202 to the second carrier 302 by the selective laser transfer process. In some embodiments, the energy of the third laser radiation 1016c is in a range from about 80 mJ to about 120 mJ.

In some embodiments, as shown in FIG. 9O, the first adhesion layer 114 on the LED chips 104 is etched to expose bottom surfaces and portions of the sidewalls of the first electrodes 112a and the second electrodes 112b of the LED chips 104 to facilitate the subsequent bonding process such that the LED chips 104 may be electrically connected to the target display panel. In some embodiments, the etching process may be similar to the etching process used in etching the first adhesion layer. In some embodiments, the etching process may include other suitable processes. In some embodiments, the first adhesion layer 114 remains on the front sides of the LED chips 104 and covers portions of the sidewalls of the first electrodes 112a and the second electrodes 112b to protect the LED chips 104, the first electrodes 112a, and the second electrodes 112b. In some embodiments, while etching the first adhesion layer 114 on the LED chips 104, a portion of the second adhesion layer 115 between the LED chips 104 may also be etched so that the second adhesion layer 115 between the LED chips 104 is thinner. The thinner portion may prevent the LED chips from accidentally adhering to the existing LED chips originally on the display panel while transferring the LED chips to the display panel. In some embodiments, the second adhesion layer 115 includes a first portion 115a between the LED chips 104 and a second portion 115b in direct contact with the LED chips 104. It should be noted that the etching process etches the first portion 115a between the LED chips 104 which are served as a hard mask to keep the second portion 115b in direct contact with the LED chips 104 intact. The thickness of the first portion 115a between the LED chips 104 is thinner than the thickness of the second portion 115b directly contacting the LED chips 104. In some embodiments, the second adhesion layer 115 has an irregular surface. In some embodiments, the thickness of the first portion 115a between the LED chips 104 is different from the thickness of the second portion 115b in direct contact with the LED chips 104. Therefore, the second carrier 302 with the LED chips (104a, 104b and 104c) is obtained.

In some embodiments, as shown in FIG. 9P, a display panel 402 with a plurality of conductive members 412 thereon is provided. The conductive members 412 may be a metal electrode. For example, the material of the conductive members 412 may include nickel (Ni), tin (Sn), indium (In), gold (Au), titanium (Ti), copper (Cu), or a combination thereof, but the present disclosure is not limited thereto. In some embodiments, the conductive member 412 may be pre-melted to have adhesive properties, or the conductive member 412 may further include solder or an adhesive material with similar adhesive function.

In some embodiments, as shown in FIG. 9P, the first electrodes 112a and the second electrodes 112b of the LED chips 104 as shown in FIG. 9O are bonded to the conductive members 412 on the display panel 402. In some embodiments, the first electrodes 112a and the second electrodes 112b are respectively in electrical contact with the conductive members 412. Next, the second carrier 302 is removed so that the LED chips 104 that need to be transferred leave the second carrier 302 and are bonded to the conductive members 412 on the display panel 402, as shown in FIG. 9Q. The LED chips 104 are transferred from the second carrier 302 to the display panel 402. In some embodiments, the LED chips (104a, 104b, and 104c) are transferred from the second carrier 302 to the display panel 402 at the same time.

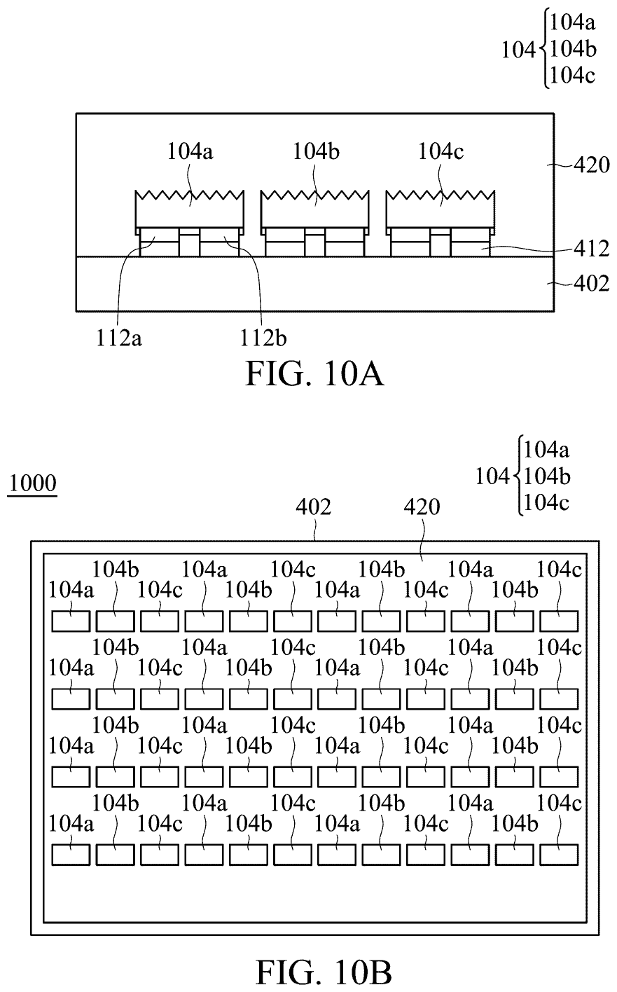

In some embodiments, as shown in FIG. 10A, a display module is provided. The display module includes a light-transmitting layer 420 disposed on the display panel 402 and covers the LED chips 104. The light-transmitting layer 420 may include polymers such as silicone or resin. The light-transmitting layer 420 may be formed by molding, glue-filling, or other suitable process.

FIG. 11B illustrates a top view of a display module 1000 according to some embodiments of the present disclosure.

In some embodiments, as shown in FIG. 10B, the display module 1000 may include a display panel 402, a plurality of LED chips 104, and a light-transmitting layer 420. The LED chips 104 are disposed on the display panel 402. The light-transmitting layer 420 is disposed on the display panel 402 and covers the LED chips 104. In some embodiments, the LED chips 104 (e.g., 104a, 104b, and 104c) include light-emitting diodes that emit different colors of light. For example, the LED chip 104a, the LED chip 104b, and the LED chip 104c include light-emitting diodes that emit red (R) light, green (G) light, and blue (B) light respectively. That is, the light-emitting diodes that emit red light, green light, and blue light respectively can be transferred to the display panel 402 simultaneously.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of the present disclosure, and that they can make various changes, substitutions, and replacements without violating the spirit and scope of the present disclosure. Therefore, the scope of protection of the present disclosure is defined by the scope of the claim attached hereto. In addition, although several preferred embodiments are disclosed in the present disclosure, they are not intended to limit the present disclosure.

What is claimed is:

1. A laser transfer structure, comprising:
a carrier;
a release layer disposed on the carrier;
a first chip disposed on the release layer; and
a plurality of first photoresist structures disposed on the carrier and surrounding the first chip.

2. The laser transfer structure as claimed in claim 1, wherein one of the first photoresist structures is in contact with the first chip.

3. The laser transfer structure as claimed in claim 1, wherein, from a top view, there is a first contact surface between one of the first photoresist structures and a first side of the first chip, the first contact surface has a first length, and a ratio of the first length to a length of the first side of the first chip is 0.5:1 to 1:1.

4. The laser transfer structure as claimed in claim 3, wherein, from a top view, there is a second contact surface between one of the first photoresist structures and a second side of the first chip, the second side is perpendicular to the first side of the first chip, the second contact surface has a second length, and a ratio of the second length to a length of the second side of the first chip is 0.5:1 to 1:1.

5. The laser transfer structure as claimed in claim 1, wherein there is a gap between the first chip and one of the first photoresist structures.

6. The laser transfer structure as claimed in claim 1, wherein, from a top view, there is a first gap between one of the first photoresist structures and a first side of the first chip, and a ratio of the first gap to a length of the first side of the first chip is 0.01:10 to 1:10.

7. The laser transfer structure as claimed in claim 6, wherein, from a top view, there is a second gap between one of the first photoresist structures and a second side of the first chip, the second side is perpendicular to the first side of the first chip, and a ratio of the second gap to a length of the second side of the first chip is 0.01:10 to 1:10.

8. The laser transfer structure as claimed in claim 1, further comprising a second chip disposed on the carrier adjacent to the first chip.

9. The laser transfer structure as claimed in claim 8, wherein the first photoresist structures surround the second chip, and one of the first photoresist structures is in contact with the first chip and the second chip.

10. The laser transfer structure as claimed in claim 8, further comprising a plurality of second photoresist structures disposed on the carrier and surrounding the second chip, wherein the second photoresist structures are separate from the first photoresist structures.

11. The laser transfer structure as claimed in claim 1, wherein the first chip has a first surface towards the carrier and a second surface opposite to the first surface, a first height is defined as a distance between an upper surface of one of the first photoresist structures and the carrier, a second height is defined as a distance between the first surface and the carrier, a third height is defined as a distance between the second surface and the carrier, and the first height is greater than or equal to the second height.

12. The laser transfer structure as claimed in claim 11, wherein the first height is greater than the second height and less than the third height.

13. A laser transfer method, comprising:
providing a first carrier with a chip and a plurality of photoresist structures surrounding the chip disposed on the first carrier;
providing a second carrier opposite to the first carrier; and
transferring the chip from the first carrier to the second carrier using laser radiation.

14. The laser transfer method as claimed in claim 13, wherein the laser radiation has an energy ranging from 80 mJ to 120 mJ.

15. The laser transfer method as claimed in claim 13, wherein there is a gap between the first carrier and the second carrier, which ranges from 70 μm to 100 μm.

16. The laser transfer method as claimed in claim 13, wherein one of the photoresist structures is in contact with the chip.

17. The laser transfer method as claimed in claim 13, wherein there is a gap between the chip and one of the photoresist structures.

18. A method for fabricating a display module, comprising:
providing a first carrier with a first chip and a plurality of first photoresist structures surrounding the first chip disposed on the first carrier;
providing a second carrier opposite to the first carrier;
transferring the first chip from the first carrier to the second carrier using first laser radiation;
providing the first carrier with a second chip and a plurality of second photoresist structures surrounding the second chip disposed on the first carrier;
transferring the second chip from the first carrier to the second carrier using second laser radiation;
providing the first carrier with a third chip and a plurality of third photoresist structures surrounding the third chip disposed on the first carrier;
transferring the third chip from the first carrier to the second carrier using third laser radiation; and
transferring the first chip, the second chip and the third chip from the second carrier to a display panel.

19. The method for fabricating a display module as claimed in claim 18, wherein the first chip, the second chip and the third chip are transferred from the second carrier to the display panel at the same time.

20. The method for fabricating a display module as claimed in claim 18, wherein the first chip, the second chip and the third chip comprise light-emitting diodes that emit different colors of light.
